(19) United States
(12) Patent Application Publication
(10) Pub. No.: US 2026/0120263 A1
(43) Pub. Date: Apr. 30, 2026

(54) AUTOMATED AND INTEGRATED PRE-ANNEAL, IN-SITU, AND POST-ANNEAL INSPECTIONS OF WAFERS DURING LASER ANNEALING

(71) Applicant: II-VI Delaware, Inc., Wilmington, DE (US)

(72) Inventors: Xiquan Wu, Suzhou (CN); Toby David Rule, Bremerton, WA (US); Martin David Bell, Kirkcaldy, Fife (GB)

(21) Appl. No.: 18/937,810

(22) Filed: Nov. 5, 2024

(30) Foreign Application Priority Data
Oct. 31, 2024 (CN) 2024115451182

(51) Int. Cl. G06T 7/00; H01L 21/67; H04N 7/18; H04N 23/90

(52) U.S. Cl. CPC G06T 7/0004; H04N 7/181; H04N 23/90; H10P 72/0436; H10P 72/0604; G06T 2207/30148

(57) ABSTRACT

A laser annealing machine that is configured to apply laser annealing to workpieces may be configured to provide automated and integrated pre-anneal, in-situ, and post-anneal inspections of wafers during laser annealing. Providing automated and integrated pre-anneal, in-situ, and post-anneal inspections may include obtaining, via at least one visual sensing device, visual data associated with a workpiece, with the visual data including one or more of pre-anneal visual data, in-situ visual data, and post-anneal, processing of the obtained visual data, and determining, based on the processing of the obtained visual data, one or more adjustments to the laser annealing applied via the laser annealing machine.

### CLAIM OF PRIORITY

This patent application claims priority to and claims benefit from Chinese (CN) patent application No. 2024115451182, filed on Oct. 31, 2024. The above identified application is hereby incorporated herein by reference in its entirety.

### TECHNICAL FIELD

Aspects of the present disclosure relate to device fabrication (e.g., semiconductor wafers) related solutions. More specifically, certain implementations of the present disclosure relate to methods and systems for implementing and utilizing automated and integrated pre-anneal, in-situ, and post-anneal inspections of wafers during laser annealing.

### BACKGROUND

Limitations and disadvantages of conventional and traditional solutions, if any existed, will become apparent to one of skill in the art, through comparison of such systems with some aspects of the present disclosure as set forth in the remainder of the present application with reference to the drawings.

### BRIEF SUMMARY

System and methods are provided for automated and integrated pre-anneal, in-situ, and post-anneal inspections of wafers during laser annealing, substantially as shown in and/or described in connection with at least one of the figures, as set forth more completely in the claims.

These and other advantages, aspects and novel features of the present disclosure, as well as details of an illustrated embodiment thereof, will be more fully understood from the following description and drawings.

### BRIEF DESCRIPTION OF THE DRAWINGS

FIG. 1 illustrates an example laser annealing machine.

FIG. 2 illustrates example images of a wafer obtained during processing in a laser annealing machine with different working distance offsets.

FIGS. 3A-3B illustrate example images of a wafer obtained during processing in a laser annealing machine.

### DETAILED DESCRIPTION

The present disclosure is directed to device fabrication (e.g., semiconductor wafers) related solutions. In particular, solutions based on the present disclosure are directed to automated and integrated pre-anneal, in-situ, and post-anneal inspections of workpieces (e.g., wafers) during laser annealing thereof (e.g., when applying lasing patterns thereto). Such automated and integrated pre-anneal, in-situ, and post-anneal inspections may be done in laser annealing machines that utilize galvanometric scanning. In such machines, hardware and software are used for laser annealing, thus essentially forming a laser engraving system that is adapted for the annealing applications. In machines using such galvanometric scanning, one or more galvanometer mirrors (also referred to herein as “galvo mirrors”) may be used to control the scanning beams that are used for the laser annealing. In some instances, the galvo mirrors may be movable, such as using corresponding galvanometer (galvo) motors.

For example, a collimated laser beam first passes through one or more (e.g., two) galvo mirrors that steer the beam in two dimensions. In some instances, additional optical components may be used, such as to focus the scanning beam onto the surface of the workpiece, thus providing the desired scanning (annealing). For example, the scanning beam may be focused using one or more lenses (e.g., telecentric lenses). In some instances, the workpiece surface may be viewed using a camera. In some instances, the camera may collect light through the same optics that are used to direct and focus the laser beam. Such camera may be used to collect images for manual positioning, or for machine vision alignment of the workpiece. In some instances, the camera may be a coaxial camera—that is, having the same orientation as the component used in projecting the scanning beam.

In various implementations based on the present disclosure, automated and integrated pre-anneal, in-situ, and post-anneal inspections may be done by use of visual data (e.g., images) that is obtained via visual sensing devices (e.g., cameras), with the visual data being processed to enable setting and/or adjusting processing (e.g., annealing) of the workpieces. The capturing and processing of visual data, and the determining of adjustments based thereon, may be done automatically—e.g., by software in the system. In some instances, microscopic imagining systems may be used to provide one or more of pre-anneal, in-situ, and post-anneal inspections of wafers. Such microscopic imaging systems may be separate from the optical path utilized by and during the annealing process. Further, the microscopic imagining system may be implemented inside the overall system cabinet and may be serviced by the automated wafer handling system. Instead, in implementations based on the present disclosure the visual (optical) system already incorporated into the machine may be used for such inspections. In this regard, transmitted-light images that may require a front-side light source may be used to measure the quality of the laser annealing spots. In particular, an optical system may be used to provide automated and integrated inspections. In this regard, fully automated/integrated control metrics may require data analysis in real-time to enable corrective actions prior to processing. Otherwise, control adjustments would have to be made between lots or on a much less frequent schedule (e.g., hourly, shift-wise, or daily). As such, use of automated and integrated may allow for enhancing the automated wafer handling and laser annealing cycle-times.

Various aspects of solutions in accordance with the present disclosure and implementations based thereon are described in more detail below with respect to the figures.

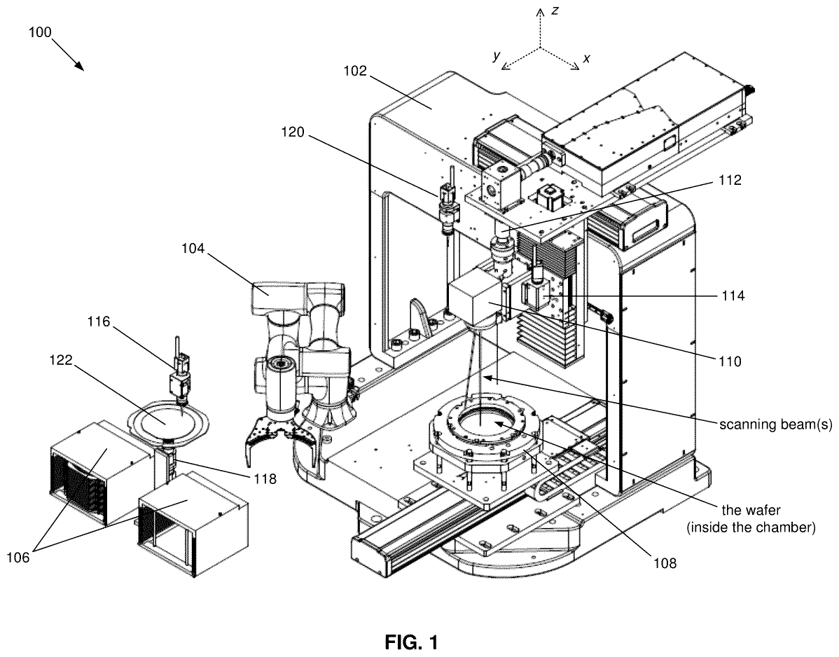

FIG. 1 illustrates an example laser annealing machine. Shown in FIG. 1 is a laser annealing machine (or simply “machine”) 100 (or a portion thereof), implemented in accordance with an example embodiment.

The machine 100 is configured for use in treating semiconductor wafers using laser annealing. In this regard, annealing is a heat treatment that may be used to alter the physical and/or chemical properties of a material. Specifically, the heat treatment performed during annealing may be used to achieve a condition to heat up the surface layer of material (usually very thin metal layer) to react with underlying bulk material (semiconductor) to form omhic contacts on the backside of the wafer without heating up the front side devices. In laser annealing a laser beam is used for the heat treatment. Laser annealing may be used during semiconductor device fabrication as one of the process steps used in fabricating a semiconductor device. In particular, laser annealing may be used to treat semiconductor wafers during semiconductor device fabrication.

The machine 100 comprises suitable hardware components and circuitry (e.g., embedded within dedicated control components (not shown) and/or within some of the hardware components of the machine) configured for facilitating laser annealing, particularly laser annealing of semiconductor-based wafers or the like.

As shown in FIG. 1, the machine 100 comprises a main structure 102, a robot arm 104, one or more wafer cassettes (containers) 106, an annealing chamber 108, a scan head 110, and a laser source 112.

The main structure 102 is configured to engage and/or house at least some of the remaining components of the machine 100. For example, the main structure 102 may comprise a base section that securely supports remaining sections of the machine, a chamber holding section (attached to or is part of the base section) that engages the annealing chamber 108, and a frame section configured to hold or engage the scan head 110 and the laser source 112 above the chamber holding section.

The scan head 110 may be configured to enable projecting laser beams emitted by the laser source 112 onto the wafer 122 within the annealing chamber 108. In various implementations, the scan head 110 may comprise optical components configured for enabling controlling and directing the laser beam emitted by the laser source 112, such that the beam may be projected (e.g., vertically—that is, downwards in the z-direction) onto the surface of the wafer 122 when placed within the annealing chamber 108. For example, the optical components comprise one or more mirrors (e.g., galvo mirrors) and one or more lenses (e.g., telecentric lenses). The scan head 112 may also comprise additional components that may be used to control the optical components, such as galvo motors that may be used in moving the galvo mirrors. These optical components may be configured to operate collaboratively, to enable controlling the laser beam emitted by the laser source 112 (and inputted into the scan head 110), to enable re-directing the laser beam such that it may be projected downwards (vertically) onto the surface of the wafer 122), as shown in FIG. 1.

In some implementations, the frame section may incorporate a scanner holding section that holds or engages the scan head 110 and the laser source 112. Further, in some implementations, one or both of the chamber holding section and the scanner holding section may be moveable (e.g., using rail-like mechanisms) to ensure alignment of the scan head 110 and the annealing chamber 108. For example, the scan head 110 may be configured to move in one direction (e.g., x-direction) whereas the annealing chamber 108 may move in different direction (e.g., y-direction), to facilitate aligning the scan head 110 during scanning. Further, the scan head 110 may further be moveable in the z-direction—that is, up and down relative to the annealing chamber 108—such as to enable focusing. Accordingly, the scan head 110 may be effectively moved (e.g., by moving it directly, or by moving other components) in 3-dimensions relative to the annealing chamber 108.

In operation, the robot arm 104 is configured to retrieve (untreated) wafer 122 from one wafer cassette 106, and to place the wafer 122 into the annealing chamber 108. Once in the annealing chamber 108, the wafer 122 is treated, which includes subjecting the wafer to laser annealing. In this regard, the wafer 122 is treated by projecting a scanning beam onto it from the scan head 110, with the laser source 112 providing the laser used in the scanning beam. For example, the scan head 110 may comprise a mirror positioned at suitable angle (e.g., 45°) to enable projecting the laser beam(s) emitted by the laser source 112 downwards (e.g., vertically, at 90° relative to the horizontal plane) onto the wafer 122 inside the annealing chamber 108, thus providing the scanning beam. Once the laser annealing is completed, the robot arm 104 retrieves the treated wafer 122 from the annealing chamber 108 and places it back (e.g., into another wafer cassette 106).

In accordance with the present disclosure, laser annealing machines (e.g., the machine 100) may incorporate an integrated visual detection system that may be configured for providing and/or supporting various visual-based functions that may be used in enhancing operation and/or performance of the laser annealing machines. In this regard, an example integrated visual detection system may comprise one or more visual sensing devices (e.g., cameras) that may be used for providing and/or supporting performing of visual-based functions in the machine, such as visual-based control, visual-based monitoring, visual-based inspections, etc.

For example, in the embodiment illustrated in FIG. 1, the machine 100 comprises a plurality of cameras comprising a coaxial camera 114, a top inspection camera 116, and a bottom inspection camera 118. The machine 100 may further comprise a main camera 120. Each of these cameras may comprise suitable hardware components (e.g., lenses, etc.) and circuitry, which may be configured to enable capturing or otherwise obtaining visual representations (e.g., still images, video, etc.), such as of particular objects and/or specific areas thereof. These cameras may be used to obtain images of the wafer surface before, during, and after the laser annealing. Such images may be used in supporting operation of the machine 100, such as for feedback, process record, and quality control purposes.

The coaxial camera 114 may be configured to obtain visual data of the wafer 122 while it is in annealing chamber 108, and particularly while it is being scanned using the scan head 112. In this regard, the coaxial camera 114 is arranged such that it has the same view orientation as the scan head 112—that is, the coaxial camera 114 obtains visual data (images) along an axis parallel to the scanning beam projected by the scan head 112. The top inspection camera 116 and the bottom inspection camera 118 may be configured to obtain visual data of, respectively, the top surface and bottom surface of each of the wafers 122 as wafers are retrieved from and/or loaded back into the wafer cassettes 106. The main camera 120 may be configured to obtain visual data of the wafer 122 while it is being handled within the machine 100—that is, while it is being handled by the robotic arm 104, while it is being placed within the annealing chamber 108, etc. As such, the main camera 120 may allow for obtaining visual data of the wafer 122 in many aspects other than in a coaxial manner as provided by the coaxial camera 114.

In various implementations based on present disclosure, integrated visual detection systems (e.g., the integrated visual detection system in the machine 100) may be configured to provide and/or support automated and integrated pre-anneal, in-situ, and post-anneal inspections of wafers, and/or in facilitating use of process-control methods associated with such inspections. In this regard, the integrated visual detection system may be configured to provide and/or support performing one or more of visual-based pre-anneal inspections, in-situ inspections, and post-anneal inspections of the wafers.

Such inspections may be then used to ensure proper and optimal processing of wafers—e.g., when applying lasing patterns thereto during annealing of wafers. In this regard, the automated and integrated pre-anneal, in-situ, and post-anneal inspections may allow for accounting for, e.g., variances in wafers. In this regard, variances within wafers and/or from wafer to wafer in production may require making adjustments to the laser annealing process to account for such variances, such as by fine-tuning of the laser annealing process. For example, the wafer or alloy-metal thicknesses may vary from the center toward the edge, and such variances between regions of the wafer may require adjusting the annealing process (e.g., by changing fine-tune parameters) to optimize yield.

However, making such adjustments may have some challenges and/or limitations. In this regard, the knowledge and experience required to realize such tuning is time consuming and may be beyond the intended scope and/or expertise of operators of an automated laser annealing machine (e.g., the machine 100). As such, a stand-alone monitoring process and manual adjustment, or an integrated, automated/in-situ process is needed. Accordingly, use of automated and integrated pre-anneal, in-situ, and post-anneal inspections as described herein may allow for enhancing processing of wafers, both in real-time (e.g., allowing for adjustments during processing of wafers), and/or in the long term (e.g., allowing for adjustments that may be applied in processing future batches).

For example, pre-anneal inspections—that is, inspection of wafers before they are processed (annealed)—may allow for making adjustments to annealing related parameters and functions before the annealing is performed, such as to preemptively account for unique features and/or characteristics of the wafer. In-situ inspections may similarly be used to allow for real-time adjustments, such as by making adjustments on the fly to account for features in the wafer that may be introduced in the course of annealing. The post-anneal inspections in turn may be used in determining adjustments for future operations—e.g., by comparing pre-processing images and post-processing images to assess effects of the annealing, and thus determine any needed changes.

In some instances, the automated and integrated pre-anneal, in-situ, and post-anneal inspections may be used to obtain information relating to wafers and/or to the annealing process applied thereto, such as by correlating obtained images and/or attributes or parameters associated therewith (e.g., transparency or opaqueness of certain areas) with pertinent attributes and parameters of wafers and features thereof. In this regard, transparency or translucence of a particular area may be indicative of whether (or not) metal is still present on the surface of the wafer, which in turn may be indicative of the quality of annealing. Electrical resistance (ohmicity) of an annealed area, for example, may be correlated to optical images and/or image features, formed by light that is reflected from or transmitted through a wafer (e.g., a silicon carbide (SiC) device wafer). Such reflections may be visible to the naked eye, but are observable in more detail, e.g., with the aid of a microscope, and may be recorded using a camera.

In various implementations based on the present disclosure, obtained images may be processed to enable assessing of various aspects of the wafers, such as based on correlating of features in the obtained images with particularly attributes, such as electrical resistance (ohmicity). Performing such image processing—that is based on such correlation(s)—may have some challenges and/or limitations, however. For example, such challenges may include the need to have information that may be used during the image processing, such as to assess correlation between optical-image features and chemical and/or performance attributes, and/or to link annealing process parameters to optical-image features. The challenges may also include needing to configure the system to provide the processing needed for the adjusting (e.g., fine-tuning) of the annealing processing. Once such challenges are addressed, image processing may be used effectively in controlling and/or enhancing wafer processing.

Accordingly, in some implementations, correlation tables that link reflected- and transmitted-light, optical-image features of single laser-annealed spots to single-spot, chemical composition, and ohmicity measurements may be used in conjunction with automated and integrated pre-anneal, in-situ, and post-anneal inspections. Further, correlation tables that link annealing process parameters (such as spot energy, energy distribution, working distance offset, alloy-metal layer thickness, and wafer surface morphology) to single-spot, optical-image features may also be built and/or updated thereafter, for use in conjunction with automated and integrated pre-anneal, in-situ, and post-anneal inspections. Such tables may be used during the processing of images, for example, to enable deriving annealing related information, which in turn may be used in fine-tuning the annealing process. In some implementations, computer algorithms that may guide process changes that accomplish fine-tuning of controllable process variables which in turn enable the most favorable annealing results may be used in conjunction with automated and integrated pre-anneal, in-situ, and post-anneal inspections. Such tables and/or algorithms may be built and/or stored into the system, and used thereafter. Further, in some instances, the tables and/or algorithms may be updated, such as based on annealing processing in the system.

Use of automated and integrated pre-anneal, post-anneal, and in-situ inspections may enable semi-automated or fully-automated fine-tuning of the back-side, laser annealing process parameters that may assure that the highest quality ohmic performance electrical contacts for silicon-carbide (SiC) semiconductor devices are being produced. For example, in some instances, the fine tuning may be done based on established correlations between optical image features (e.g., size, contrast, and granularity) of annealed spots with particular chemical attributes—e.g., the chemical ratio of nickel (Ni) from the alloy-metal layer to silicon (Si) from the underlying SiC wafer, which produces the most favored nickel-silicide composition (e.g., NiSi rather than NiSi2 or Ni2Si) that yields the highest conductivity spot. In some instances, the fine tuning may be done based on established correlations between the chemical ratio of Ni to Si and electrical conductivity measurements on whole wafers.

In various implementation, to facilitate automated and integrated pre-anneal, in-situ, and post-anneal inspections, images of the wafers may be obtained used a plurality of cameras, each providing different perspective and/or capturing different features or aspects. For example, in the machine 100, cameras 114, 116, 118, and 120 may operate collaboratively in obtaining images for facilitating automated and integrated pre-anneal, in-situ, and post-anneal inspections. In this regard, cameras 116 and 118 may be used in obtaining, respectively, images of the top and bottom of the wafers, such as pre-annealing images (e.g., when unprocessed wafer 122 is retrieved from the wafer cassette 106), and/or post-annealing images (e.g., when the processed wafer 122 is loaded into the wafer cassette 106). The cameras 116 and 118 may be configured for obtaining images of only portions or sections of the wafer (e.g., edge areas). The cameras 114 and 120 may be used in obtaining in-situ images—that is, images while the wafer 120 is being processed (annealed). In this regard, the camera 114 may be configured for obtaining images of only portions or sections of the wafer (e.g., edge areas) whereas the camera 120 may be configured for obtaining images of the wafer as a whole. As shown in the embodiment illustrated in FIG. 1, cameras 114 and 120 may be configured to obtain only images of the top-side of the wafers. In some instances, one or both of the cameras 114 and 120 may be used in obtaining pre-anneal and/or post-anneal images.

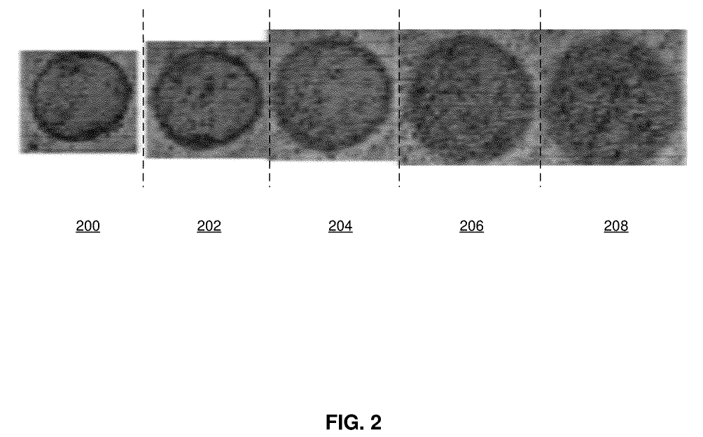

In some implementations, different image working-distance offsets may be utilized, such as to achieve a range of single-spot, energy density patterns. This is illustrated and described in more detail with respect to FIG. 2.

The obtained images may be processed, such as to enable obtaining of information relating to the wafers, which may in turn be used in controlling (e.g., fine-tuning) the annealing process, such as to account for variances in the wafers (e.g., wafer-to-wafer variances, batch-to-batch variances, etc.), as described herein. In this regard, the images may be processed in real-time (active processing), to enable making real-time adjustments in the course of annealing processing. Images may also be stored and used (e.g., processed) subsequently, to enable honing of the annealing functions. In some instances, at least a portion of the processing of images may be done directly within the system (e.g., using existing or added processing circuitry in the machine 100). Alternatively or additionally, at least a portion of the processing of images may be done using separate, dedicated processing resources, such as in local or remote processing platforms (e.g., computers or the like) that are configured to communicate with the machine 100, to enable receiving the obtained images or information based thereon, and/or to communicate back control data (e.g., parameters or adjustments thereto) generated based on the processing of images. In some instances, such local or remote processing platforms may be configured to aggregate images and/or information based thereon originating from multiple machines, to further enhance annealing across the multiple machines.

In some implementations, artificial intelligence and/or machine learning techniques may be used, particularly in conjunction with image processing, such as to enhance and/or optimize imaging related functions or operations. For example, processing circuitry (e.g., within the machine 100 itself, and/or within the local or remote processing platforms used in the processing of images) may be configured to implement and/or use deep learning techniques and/or algorithms, such as by use of deep neural networks (e.g., one or more of convolutional neural network (CNN), a generative adversarial network (GAN), residual channel attention network (RCAN), residual dense network (RDN), etc.), and/or may utilize any suitable form of artificial intelligence based processing techniques or machine learning processing functionality (e.g., for image analysis). Such artificial intelligence based image analysis may be configured to, e.g., analyze acquired images of wafers, such as to identify, segment, label, and track features in the images meeting particular criteria and/or having particular characteristics.

FIG. 2 illustrates example images of a wafer obtained during processing in a laser annealing machine with different working distance offsets. Shown in FIG. 2 are images 200-208.

In this regard, images 200-208 correspond to images of a wafer when processed (annealed) using different offsets—namely with image 200 representing an image of a wafer with zero offset, image 202 representing an image of the wafer with 1× offset, image 204 representing an image of the wafer with 2× offset, image 206 representing an image of the wafer with 3× offset, and image 208 representing an image of the wafer with 4× offset.

As illustrated by images 200-208, use of different offsets results in images of different quality, thus yielding different information that may be obtained from processing the image. For example, image 200 (the zero offset image) has a high-contrast, blackish outer ring with a uniformly blue center and overall smaller size compared to image 208 (the 4× offset image) which displays a substantially diffuse, grayish outer ring with a barely identifiable, blue-tinted center, and overall larger size. As such, when sensing contrast, colors and size, the system may be capable of adjusting overall spot energy, spot size and energy distribution by adjusting the laser power and working distance offset.

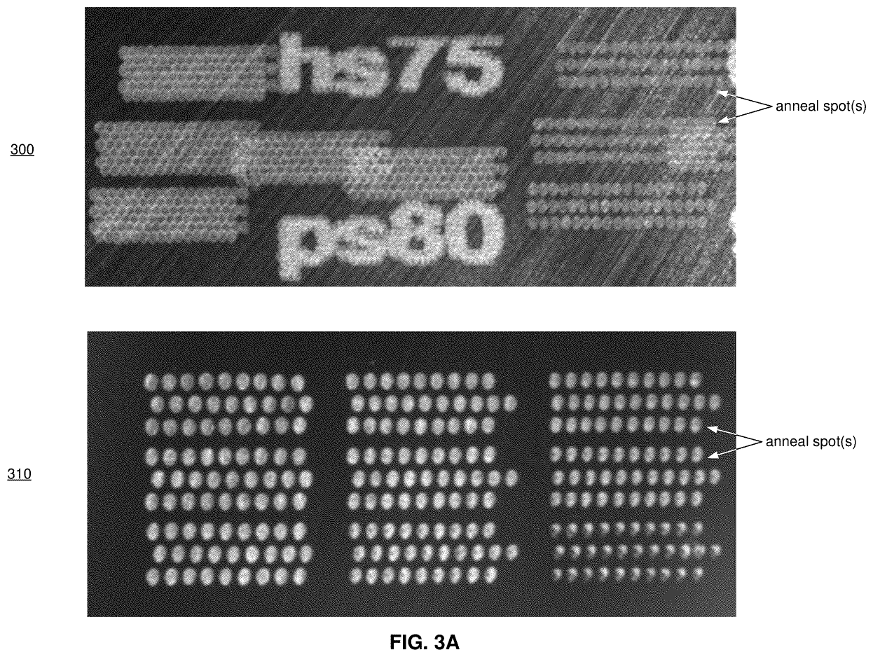

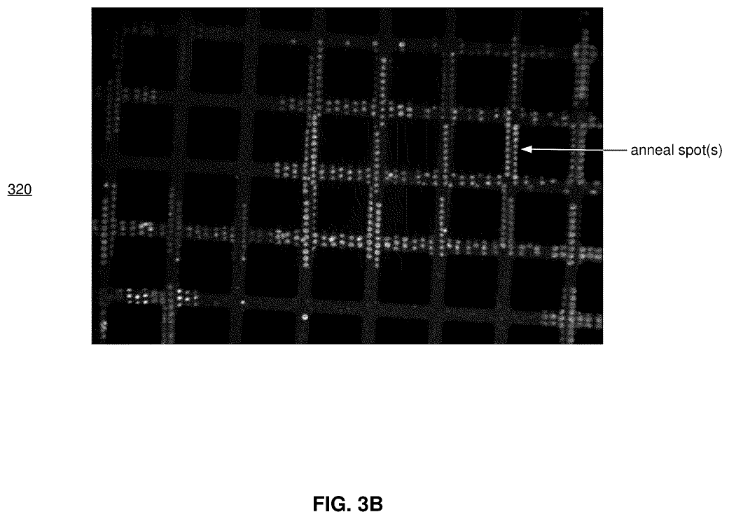

FIGS. 3A-3B illustrate example images of wafer(s) obtained during processing in a laser annealing machine. Shown in FIGS. 3A-3B are images 300, 310, and 320.

In this regard, images 300 and 310 represent example anneal side images of a wafer (particularly images of the surface of the wafer) processed in a laser annealing machine (e.g., the machine 100 of FIG. 1). Image 320 represents an example transmission image of a wafer taken in a laser annealing machine (e.g., the machine 100 of FIG. 1), particularly during the annealing, such as using a camera in the system, such as a device side camera (e.g., the camera 114 in the machine 100).

Images such as images 300, 310, and 320 may be obtained and used for feedback and quality control during wafer processing, such as to ensure wafer to wafer repeatability, to reduce potential batch failure, both for in-process and post-processing analysis. For example, the images 300, 310, and 320 may be obtained and used during automated and integrated pre-anneal, in-situ, and post-anneal inspections based operations, as described herein. In particular, these images may be processed, such as to obtain information relating to features therein (e.g., the anneal spots), with that information being used in turn to help fine-tune the annealing processing. For example, attributes (e.g., transparency) of these features may be assessed, and then annealing related attributes (e.g., Electrical resistance (ohmicity), chemical composition, etc.) may be determined, such as using correlation tables. The annealing related attributes may then be used in determining any needed adjustments to annealing related functions and/or parameters.

An example system, in accordance with the present disclosure, comprises a laser annealing machine configured to apply laser annealing to workpieces, where the laser annealing machine comprises one or more handling components for handling the workpieces; one or more annealing components configured for applying the laser annealing to the workpieces; and an integrated visual detection system comprising one or more visual sensing devices configured to obtain visual data associated with the workpieces and/or the applying of the laser annealing to the workpieces; where applying the laser annealing to each workpiece comprises applying a scanning beam onto a surface of the workpiece based on a scan pattern; and one or more processing circuits configured to provide automated and integrated pre-anneal, in-situ, and post-anneal inspections, where providing automated and integrated pre-anneal, in-situ, and post-anneal inspections comprises obtaining, via at least one visual sensing device, visual data associated with a workpiece, where the visual data comprises one or more of pre-anneal visual data, in-situ visual data, and post-anneal visual data; and processing the obtained visual data; and then determining, based on the processing of the obtained visual data, one or more adjustments to the laser annealing applied via the laser annealing machine.

In an example embodiment, the one or more processing circuits are configured to, when processing the obtained visual data, determine information relating to the workpieces and/or to the applying of laser annealing to the workpieces.

In an example embodiment, the one or more processing circuits are configured to, when determining the information, assess attributes and/or parameters associated with the obtained visual data.

In an example embodiment, the attributes and/or parameters associated with the obtained visual data comprise transparency and/or contrast for a particular area in the obtained visual data.

In an example embodiment, the one or more processing circuits are configured to, when determining the information, assess attributes and/or parameters associated with workpieces.

In an example embodiment, the attributes and/or parameters associated with workpieces comprise electrical resistance for at least one area in at least one workpiece.

In an example embodiment, the attributes and/or parameters associated with workpieces comprise chemical composition for at least one area in at least one workpiece.

In an example embodiment, the one or more processing circuits are configured to determine at least one of the one or more adjustments based on a correlation between one or more features of the obtained visual data and one or more attributes of the workpiece.

In an example embodiment, the one or more features of the obtained visual data comprise at least one of size, contrast, and granularity.

In an example embodiment, the one or more processing circuits are configured to determine the one or more features of the obtained visual data for one or more annealed spots in the obtained visual data.

In an example embodiment, the one or more attributes of the workpiece comprise chemical attributes and/or electrical resistivity attributes.

In an example embodiment, the one or more processing circuits are configured to determine a correlation between one or more features of the obtained visual data and one or more attributes of the workpiece based on one or more correlation tables.

In an example embodiment, the one or more processing circuits are configured to update at least one correlation of the one or more correlation tables based on one or both of the processing of the obtained visual data and the determining of the one or more adjustments.

In an example embodiment, the one or more visual sensing devices comprises a coaxial camera configured to obtain visual data of a portion of workpieces during processing of the workpieces.

In an example embodiment, the one or more visual sensing devices comprise a main camera configured to obtain visual data of a whole workpiece during processing of the workpieces.

In an example embodiment, the one or more visual sensing devices comprise a top inspection camera configured to obtain visual data of a top-side of workpieces during one or both of retrieving and returning of the workpieces.

In an example embodiment, the one or more visual sensing devices comprise a bottom inspection camera configured to obtain visual data of a bottom-side of workpieces during one or both of retrieving and returning of the workpieces.

In an example embodiment, the laser annealing machine comprises the one or more processing circuits.

In an example embodiment, the system further comprises a processing device separate from the laser annealing machine, where the processing device comprises the one or more processing circuits.

In an example embodiment, the processing device is configured to communicate with the laser annealing machine, where the communicating comprises receiving from the laser annealing machine the obtained visual data, and transmit to the laser annealing machine one or both of information relating to the processing of the obtained visual data and/or at least one of the one or more adjustments.

As utilized herein, “and/or” means any one or more of the items in the list joined by “and/or”. As an example, “x and/or y” means any element of the three-element set {(x), (y), (x, y)}. In other words, “x and/or y” means “one or both of x and y.” As another example, “x, y, and/or z” means any element of the seven-element set {(x), (y), (z), (x, y), (x, z), (y, z), (x, y, z)}. In other words, “x, y and/or z” means “one or more of x, y, and z.” As utilized herein, the term “exemplary” means serving as a non-limiting example, instance, or illustration. As utilized herein, the terms “for example” and “e.g.” set off lists of one or more non-limiting examples, instances, or illustrations.

As utilized herein the terms “circuits” and “circuitry” refer to physical electronic components (e.g., hardware), and any software and/or firmware (“code”) that may configure the hardware, be executed by the hardware, and or otherwise be associated with the hardware. As used herein, for example, a particular processor and memory (e.g., a volatile or non-volatile memory device, a general computer-readable medium, etc.) may comprise a first “circuit” when executing a first one or more lines of code and may comprise a second “circuit” when executing a second one or more lines of code. Additionally, a circuit may comprise analog and/or digital circuitry. Such circuitry may, for example, operate on analog and/or digital signals. It should be understood that a circuit may be in a single device or chip, on a single motherboard, in a single chassis, in a plurality of enclosures at a single geographical location, in a plurality of enclosures distributed over a plurality of geographical locations, etc. Similarly, the term “module” may, for example, refer to a physical electronic component (e.g., hardware) and any software and/or firmware (“code”) that may configure the hardware, be executed by the hardware, and or otherwise be associated with the hardware.

As utilized herein, circuitry or module is “operable” to perform a function whenever the circuitry or module comprises the necessary hardware and code (if any is necessary) to perform the function, regardless of whether performance of the function is disabled or not enabled (e.g., by a user-configurable setting, factory trim, etc.).

Other embodiments of the invention may provide a non-transitory computer readable medium and/or storage medium, and/or a non-transitory machine readable medium and/or storage medium, having stored thereon, a machine code and/or a computer program having at least one code section executable by a machine and/or a computer, thereby causing the machine and/or computer to perform the processes as described herein.

Accordingly, various embodiments in accordance with the present invention may be realized in hardware, software, or a combination of hardware and software. The present invention may be realized in a centralized fashion in at least one computing system, or in a distributed fashion where different elements are spread across several interconnected computing systems. Any kind of computing system or other apparatus adapted for carrying out the methods described herein is suited. A typical implementation may comprise one or more application specific integrated circuit (ASIC), one or more field programmable gate array (FPGA), and/or one or more processor (e.g., x86, x64, ARM, PIC, and/or any other suitable processor architecture) and associated supporting circuitry (e.g., storage, DRAM, FLASH, bus interface circuits, etc.). Each discrete ASIC, FPGA, Processor, or other circuit may be referred to as “chip,” and multiple such circuits may be referred to as a “chipset.” Another implementation may comprise a non-transitory machine-readable (e.g., computer readable) medium (e.g., FLASH drive, optical disk, magnetic storage disk, or the like) having stored thereon one or more lines of code that, when executed by a machine, cause the machine to perform processes as described in this disclosure. Another implementation may comprise a non-transitory machine-readable (e.g., computer readable) medium (e.g., FLASH drive, optical disk, magnetic storage disk, or the like) having stored thereon one or more lines of code that, when executed by a machine, cause the machine to be configured (e.g., to load software and/or firmware into its circuits) to operate as a system described in this disclosure.

Various embodiments in accordance with the present invention may also be embedded in a computer program product, which comprises all the features enabling the implementation of the methods described herein, and which when loaded in a computer system is able to carry out these methods. Computer program in the present context means any expression, in any language, code or notation, of a set of instructions intended to cause a system having an information processing capability to perform a particular function either directly or after either or both of the following: a) conversion to another language, code or notation; b) reproduction in a different material form.

While the present method and/or system has been described with reference to certain implementations, it will be understood by those skilled in the art that various changes may be made and equivalents may be substituted without departing from the scope of the present method and/or system. In addition, many modifications may be made to adapt a particular situation or material to the teachings of the present disclosure without departing from its scope. Therefore, it is intended that the present method and/or system is not limited to the particular implementations disclosed, but that the present method and/or system will include all implementations falling within the scope of the appended claims.

What is claimed is:

1. A system comprising:
a laser annealing machine configured to apply laser annealing to workpieces, wherein the laser annealing machine comprises:
one or more handling components for handling the workpieces;
one or more annealing components configured for applying the laser annealing to the workpieces; and
an integrated visual detection system comprising one or more visual sensing devices configured to obtain visual data associated with the workpieces and/or the applying of the laser annealing to the workpieces;
wherein applying the laser annealing to each workpiece comprises applying a scanning beam onto a surface of the workpiece based on a scan pattern; and
one or more processing circuits configured to provide automated and integrated pre-anneal, in-situ, and post-anneal inspections, wherein providing automated and integrated pre-anneal, in-situ, and post-anneal inspections comprises:
obtaining, via at least one visual sensing device, visual data associated with a workpiece, wherein the visual data comprises one or more of pre-anneal visual data, in-situ visual data, and post-anneal visual data; and
processing the obtained visual data; and
determining, based on the processing of the obtained visual data, one or more adjustments to the laser annealing applied via the laser annealing machine.

2. The system of claim 1, wherein the one or more processing circuits are configured to, when processing the obtained visual data, determine information relating to the workpieces and/or to the applying of laser annealing to the workpieces.

3. The system of claim 2, wherein the one or more processing circuits are configured to, when determining the information, assess attributes and/or parameters associated with the obtained visual data.

4. The system of claim 3, wherein the attributes and/or parameters associated with the obtained visual data comprise transparency and/or contrast for a particular area in the obtained visual data.

5. The system of claim 2, wherein the one or more processing circuits are configured to, when determining the information, assess attributes and/or parameters associated with workpieces.

6. The system of claim 5, wherein the attributes and/or parameters associated with workpieces comprise electrical resistance for at least one area in at least one workpiece.

7. The system of claim 5, wherein the attributes and/or parameters associated with workpieces comprise chemical composition for at least one area in at least one workpiece.

8. The system of claim 1, wherein the one or more processing circuits are configured to determine at least one of the one or more adjustments based on a correlation between one or more features of the obtained visual data and one or more attributes of the workpiece.

9. The system of claim 8, wherein the one or more features of the obtained visual data comprise at least one of size, contrast, and granularity.

10. The system of claim 8, wherein the one or more processing circuits are configured to determine the one or more features of the obtained visual data for one or more annealed spots in the obtained visual data.

11. The system of claim 8, wherein the one or more attributes of the workpiece comprise chemical attributes and/or electrical resistivity attributes.

12. The system of claim 1, wherein the one or more processing circuits are configured to determine a correlation between one or more features of the obtained visual data and one or more attributes of the workpiece based on one or more correlation tables.

13. The system of claim 12, wherein the one or more processing circuits are configured to update at least one correlation of the one or more correlation tables based on one or both of the processing of the obtained visual data and the determining of the one or more adjustments.

14. The system of claim 1, wherein the one or more visual sensing devices comprises a coaxial camera configured to obtain visual data of a portion of workpieces during processing of the workpieces.

15. The system of claim 1, wherein the one or more visual sensing devices comprise a main camera configured to obtain visual data of a whole workpiece during processing of the workpieces.

16. The system of claim 1, wherein the one or more visual sensing devices comprise a top inspection camera configured to obtain visual data of a top-side of workpieces during one or both of retrieving and returning of the workpieces.

17. The system of claim 1, wherein the one or more visual sensing devices comprise a bottom inspection camera configured to obtain visual data of a bottom-side of workpieces during one or both of retrieving and returning of the workpieces.

18. The system of claim 1, wherein the laser annealing machine comprises the one or more processing circuits.

19. The system of claim 1, further comprising a processing device separate from the laser annealing machine, wherein the processing device comprises the one or more processing circuits.

20. The system of claim 19, wherein the processing device is configured to communicate with the laser annealing machine, wherein the communicating comprises receiving from the laser annealing machine the obtained visual data, and transmitting to the laser annealing machine one or both of information relating to the processing of the obtained visual data and/or at least one of the one or more adjustments.
